(19) United States
(12) Patent Application Publication
(10) Pub. No.: US 2024/0088852 A1
(43) Pub. Date: Mar. 14, 2024

(54) AMPLIFIER CIRCUIT, SWITCHING POWER SUPPLY CIRCUIT, AND SWITCHING POWER SUPPLY DEVICE

(71) Applicant: ROHM CO., LTD., Kyoto (JP)

(72) Inventors: Kanto KUBOTA, Kyoto (JP); Kazuhiro MURAKAMI, Kyoto (JP); Kunimasa TANAKA, Kyoto (JP)

(21) Appl. No.: 18/517,353

(22) Filed: Nov. 22, 2023

Related U.S. Application Data
(63) Continuation of application No. PCT/JP22/18522, filed on Apr. 22, 2022.

(30) Foreign Application Priority Data
May 31, 2021 (JP) 2021-090925

(51) Int. Cl. H03F 3/45; H02M 3/155

(52) U.S. Cl. CPC H03F 3/45197; H02M 3/155; H03F 1/26

(57) ABSTRACT

An amplifier circuit configured to generate an error voltage corresponding the difference between a target voltage and a reference voltage includes: a first differential input pair having a first transistor configured to receive the target voltage at its gate and a second transistor configured to receive the reference voltage at its gate; and a second differential input pair having a third transistor configured to receive the target voltage at its gate and a fourth transistor configured to receive the reference voltage at its gate. The amplifier circuit generates the error voltage based on the reference voltage by using the first or second differential input pair. The first and second transistors are formed as P-channel MOSFETs and the third and fourth transistors are formed as N-channel MOSFETs.

### CROSS-REFERENCE TO RELATED APPLICATIONS

This nonprovisional application is a continuation application of International Patent Application No. PCT/JP2022/018522 filed on Apr. 22, 2022, which claims priority Japanese Patent Application No. 2021-090925 filed on May 31, 2021, the entire contents of which are hereby incorporated by reference.

### TECHNICAL FIELD

The present disclosure relates to amplifier circuits, switching power supply circuits, and switching power supply devices.

### BACKGROUND ART

Various devices incorporate an amplifier circuit that generates an error voltage corresponding to a differential voltage between two voltages. For example, a switching power supply device that generates an output voltage by switching an input voltage incorporates an amplifier circuit that compares a feedback voltage based on the output voltage with a reference voltage to generate an error voltage corresponding to the differential voltage between those voltages. Here, switching operation is performed based on the error voltage.

### CITATION LIST

### Patent Literature

Patent Document 1: JP-A-2019-221099

### BRIEF DESCRIPTION OF DRAWINGS

FIG. 1 is an overall configuration diagram of a switching power supply device according to an embodiment of the present disclosure.

FIG. 2 is an exterior view of a semiconductor device according to an embodiment of the present disclosure.

FIG. 3 is a diagram showing the waveform of a signal (SET) according to an embodiment of the present disclosure.

FIG. 4 is a diagram showing the relationship among a plurality of signals according to an embodiment of the present disclosure.

FIG. 5A is a diagram showing the configuration of a slope voltage generation circuit according to an embodiment of the present disclosure.

FIG. 5B is a diagram illustrating a slope voltage according to an embodiment of the present disclosure.

FIG. 6 is a diagram illustrating the switching operation performed by a semiconductor device according to an embodiment of the present disclosure.

FIG. 7 is a diagram showing how a reference voltage varies according to an embodiment of the present disclosure.

FIG. 8 is a diagram showing the configuration of an error amplifier according to a reference example.

FIG. 9 is a diagram showing the configuration of an error amplifier according to Practical Example 1 as an embodiment of the present disclosure.

FIG. 10 is a diagram illustrating two states according to Practical Example 1 as an embodiment of the present disclosure.

FIG. 11 is a diagram comparing noise characteristics between the reference example and Practical Example 1.

### DESCRIPTION OF EMBODIMENTS

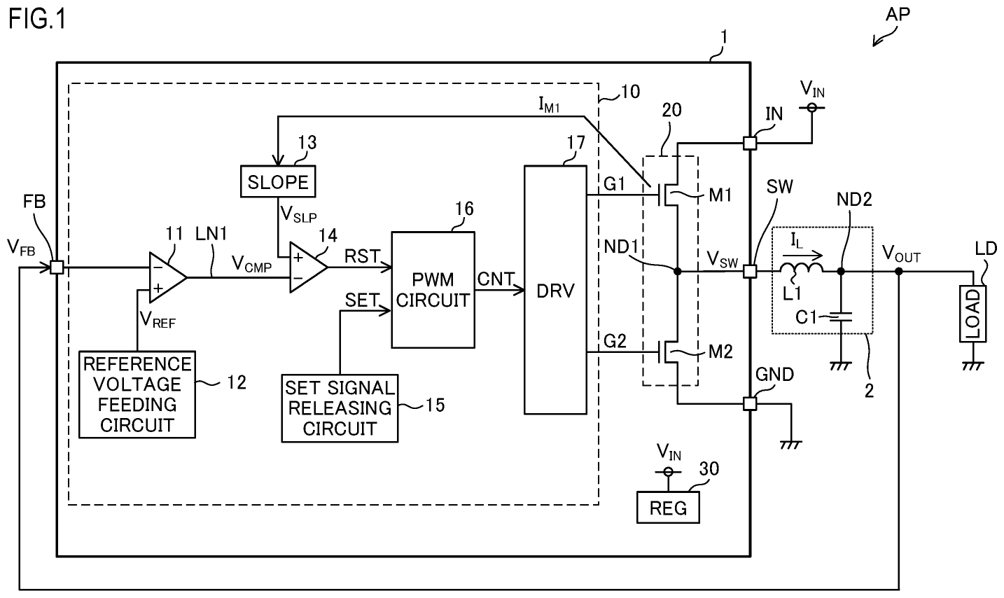

Hereinafter, examples of implementing the present disclosure will be described specifically with reference to the accompanying drawings. Among the diagrams referred to in the course, the same parts are identified by the same reference signs, and in principle no overlapping description of the same parts will be repeated. In the present description, for the sake of simplicity, symbols and reference signs referring to information, signals, physical quantities, elements, parts, and the like are occasionally used with omission or abbreviation of the names of the information, signals, physical quantities, elements, parts, and the like corresponding to those symbols and reference signs. For example, the high-side transistor described later and identified by the reference sign “M1” (see FIG. 1) is sometimes referred to as “high-side transistor M1” and other times abbreviated to “transistor M1”, both referring to the same entity.

First, some of the terms used to describe embodiments of the present disclosure will be defined. “Line” denotes a wiring across or to which an electrical signal is passed or applied. “Ground” denotes a reference conductor at a reference potential of 0 V (zero volts), or to a potential of 0 V itself. A reference conductor is formed of an electrically conductive material such as metal. A potential of 0 V is occasionally referred to as a ground potential. In embodiments of the present disclosure, any voltage mentioned with no particular reference mentioned is a potential relative to the ground. “Level” denotes the level of a potential, and for any signal or voltage of interest, “high level” is a potential higher than “low level”. Any digital signal takes high or low level as its signal level. For any signal or voltage of interest, its being at high level means, more precisely, its level being equal to high level, and its being at low level means, more precisely, its level being equal to low level. For any signal or voltage of interest, a transition from low level to high level is termed an up edge (or rising edge), and a transition from high level to low level is termed a down edge (or falling edge).

For any transistor configured as an FET (field-effect transistor), which can be a MOSFET, “on state” refers to a state where the drain-source channel of the transistor is conducting, and “off state” refers to a state where the drain-source channel of the transistor is not conducting (cut off). Similar definitions apply to any transistor that is not classified as an FET. Unless otherwise stated, any MOSFET can be understood to be an enhancement MOSFET. “MOSFET” is an abbreviation of “metal-oxide-semiconductor field-effect transistor”. In the following description, for any transistor, its being in the on or off state is occasionally expressed simply as its being on or off respectively. For any transistor, a period in which it is in the on state is often referred to as the on period, and a period in which it is in the off state is often referred to as the off period.

For any signal that takes high or low level as its signal level, the period in which the signal is at high level is referred to as the high-level period and the period in which the signal is at low level is referred to as the low-level period. The same applies to any voltage that takes high or low level as its voltage level. Unless otherwise stated, wherever “connection” is discussed among a plurality of parts constituting a circuit, as among circuit elements, wirings (lines), nodes, and the like, the term is to be understood to denote “electrical connection.”

FIG. 1 is an overall configuration diagram of a switching power supply device AP according to an embodiment of the present disclosure. The switching power supply device AP in FIG. 1 is configured as a buck (step-down) DC/DC converter that generates from an input voltage V_{IN} an output voltage V_{OUT} lower than the input voltage V_{IN}. The input voltage V_{IN} and the output voltage V_{OUT} are each a positive direct-current voltage. The switching power supply device AP includes a semiconductor device 1 as a switching power supply circuit and a rectifying-smoothing circuit 2 that generates the output voltage V_{OUT} by rectifying and smoothing a switching voltage V_{SW}, which will be described later. The semiconductor device 1 is what is called a power IC. The rectifying-smoothing circuit 2 includes an inductor L1 and an output capacitor C1.

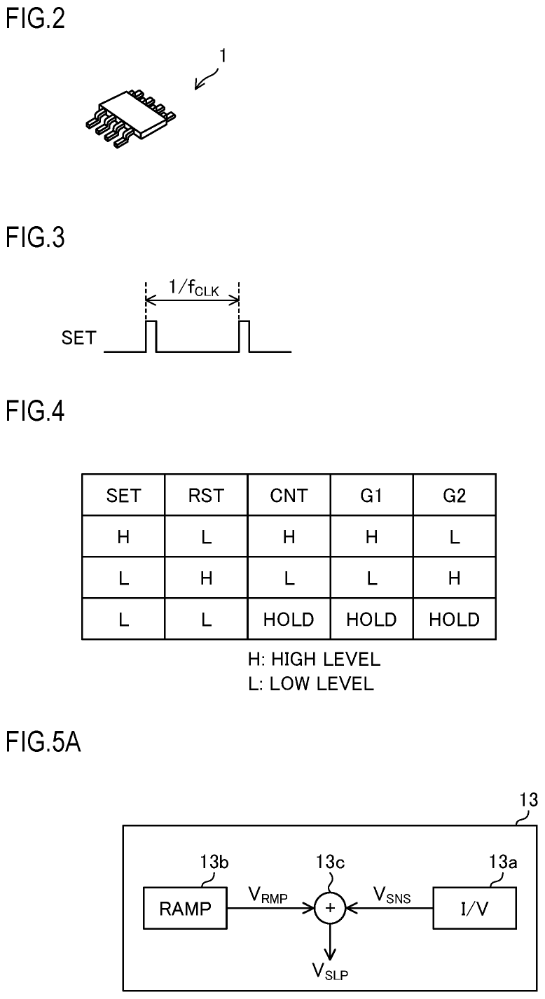

FIG. 2 shows an example of the exterior appearance of the semiconductor device 1. The semiconductor device 1 is an electronic component that includes a semiconductor chip having a semiconductor integrated circuit formed on a semiconductor substrate, a package (case) housing the semiconductor chip, and a plurality of external terminals exposed out of the package to outside the semiconductor device 1. Sealing the semiconductor chip in the package (case) formed of resin yields the semiconductor device 1. The circuits (including a control block 10, an output stage circuit 20, and an internal power supply circuit 30, which will be described later) constituting the semiconductor device 1 are included in the semiconductor integrated circuit mentioned above. The number of external terminals, and the type of package, of the semiconductor device 1 shown in FIG. 2 are merely illustrative, and can be designed as desired.

The semiconductor device 1 is provided with a plurality of external terminals, of which some are shown in FIG. 1, namely external terminals IN, SW, GND, and FB. The external terminal IN is an input terminal at which to receive the input voltage V_{IN}, and the external terminal GND is a ground terminal to be connected to a ground. In the switching power supply device AP, the input terminal IN is fed with the input voltage V_{IN}, and the ground terminal GND is connected to the ground. Since the input voltage V_{IN} has a positive direct-current voltage value, the ground terminal GND is arranged on the lower potential side of the input terminal IN. The external terminal SW is a switching terminal to be connected to a node ND1, which will be described later. The external terminal FB is a feedback terminal at which to receive a feedback voltage V_{FB}. In the switching power supply device AP, a node ND2 to which the output voltage V_{OUT} is applied is connected directly to the feedback terminal FB. Accordingly, the feedback voltage V_{FB} appearing at the feedback terminal FB is equal to the output voltage V_{OUT}.

The semiconductor device 1 includes a control block 10, an output stage circuit 20, and an internal power supply circuit 30. While the semiconductor device 1 also includes a reverse current detection circuit, a fault detection/protection circuit, and the like, these are omitted from illustration and description. The output stage circuit 20 may be one that is provided outside, and is externally connected to, the semiconductor device 1.

The output stage circuit 20 includes a high-side transistor M1, which functions as an output transistor, and a low-side transistor M2, which functions as a synchronous rectification transistor, and switches the input voltage V_{IN} under the control of the control block 10. The transistors M1 and M2 are connected in series with each other. That is, the output stage circuit 20 includes a series circuit of the transistors M1 and M2. Using the transistors M1 and M2, the switching power supply device AP performs direct current-to-direct current conversion by synchronous rectification. The transistors M1 and M2 are each configured as an N-channel MOSFETs. A modification is possible in which the transistor M1 is configured as a P-channel MOSFET. The transistor M2 may be replaced with a diode, in which case the switching power supply device AP performs direct current-to-direct current conversion by asynchronous rectification.

The drain of the transistor M1 is connected to the input terminal IN, and thus receives the input voltage V_{IN}. The source of the transistor M1 and the drain of the transistor M2 are connected together at a node ND1. The source of the transistor M2 is connected to the ground terminal GND (and is thus connected to the ground). The voltage appearing at the node ND1 is referred to as the switching voltage and is identified by the symbol “V_{SW}”. Inside the semiconductor device 1, the switching terminal SW is connected to the node ND1; outside the semiconductor device 1, the switching terminal SW is connected to one terminal of the inductor L1. Thus, the switching terminal SW lies between one terminal of the inductor L1 and the node ND1. The other terminal of the inductor L1 is connected to a node ND2. At the node ND2 appears the output voltage V_{OUT}. The output capacitor C1 is connected between the node ND2 and the ground. In a case where the transistor M1 is configured as a P-channel MOSFET, the relationship between the source and the drain of the transistor M1 is reversed compared with what has been described above (specifically, the source and the drain of the transistor M1 are connected to the input terminal IN and the node ND1 respectively).

In FIG. 1, the reference sign “LD” identifies a load that is connected between the node ND2 and the ground. The load LD can be any load that is driven with the output voltage V_{OUT}. The current through the inductor L1 is referred to as the inductor current and is identified by the symbol “I_{L}”.

The control block 10 turns the transistors M1 and M2 on and off based on information on the output voltage V_{OUT} (specifically, the feedback voltage V_{F}B) and information on the inductor current I_{L} and thereby stabilizes the output voltage V_{OUT} at a predetermined target voltage V_{TG} (e.g., 0.9 V). That is, the control block 10 can drive the transistors M1 and M2 by what is known as current-mode control. Here, the current I_{M1} that passes through the transistor M1 during its on period is used as the information on the inductor current I_{L}.

The control block 10 controls the state of the transistor M1 by feeding its gate with a gate signal G1, and controls the state of the transistor M2 by feeding its gate with a gate signal G2. The transistor M1 is on in the high-level period of the gate signal G1, and is off in the low-level period of the gate signal G1. The transistor M2 is on in the high-level period of the gate signal G2, and is off in the low-level period of the gate signal G2. By the control block 10 the state of the output stage circuit 20 is controlled to be set to one of a high-output state, a low-output state, and a both-off state. In the high-output state, the transistor M1 is on and the transistor M2 is off. In the low-output state, the transistor M1 is off and the transistor M2 is on. In the both-off state, the transistors M1 and M2 are both off. It does not occur that the transistors M1 and M2 are both on.

The internal power supply circuit 30 generates from the input voltage V_{IN} a predetermined internal supply voltage. The circuits that constitute the control block 10 operate based on the internal supply voltage. A plurality of internal supply voltages may be used.

The control block 10 includes an error amplifier 11, a reference voltage feeding circuit 12, a slope voltage generation circuit 13, a main comparator 14, a set signal releasing circuit 15, a PWM circuit 16, and a gate driver 17. “PWM” is short for pulse-width modulation.

The error amplifier 11 has an inverting input terminal, a non-inverting input terminal, and an output terminal. The inverting input terminal of the error amplifier 11 is connected to the feedback terminal FB. Thus the inverting input terminal of the error amplifier 11 is fed with the feedback voltage V_{FB}. The non-inverting input terminal of the error amplifier 11 is fed with a reference voltage V_{REF} from the reference voltage feeding circuit 12. The output terminal of the error amplifier 11 is connected to a line LN1. The error amplifier 11 generates an error voltage V_{CMP} corresponding to the differential voltage between the feedback voltage V_{FB}, which is fed to the inverting input terminal of the error amplifier 11, and the reference voltage V_{REF}, which is fed to the non-inverting input terminal of the error amplifier 11. The error amplifier 11 produces the error voltage V_{CMP} on the line LN1 by directing electric charge carried by an error current signal corresponding to the differential voltage into or out of the line LN1. Specifically, if the reference voltage V_{REF} is higher than the feedback voltage V_{FB}, the error amplifier 11 outputs a current serving as the error current signal toward the line LN1 so as to increase the error voltage V_{CMP}; if the feedback voltage V_{FB} is higher than the reference voltage V_{REF}, the error amplifier 11 draws toward itself a current serving as the error current signal from the line LN1 so as to decrease the error voltage V_{CMP}. As the absolute value of the differential voltage between the reference voltage V_{REF} and the feedback voltage V_{FB} increases, the magnitude of the current serving as the error current signal increases. A phase compensator (unillustrated) composed of a series circuit of a resistor and a capacitor may be provided between the line LN1 and the ground, in which case the phase compensator cooperates with the error amplifier 11 to produce the error voltage V_{CMP} on the line LN1.

The reference voltage feeding circuit 12 generates the reference voltage V_{REF} and feeds it to the non-inverting input terminal of the error amplifier 11.

The slope voltage generation circuit 13 generates a slope voltage V_{SLP} that corresponds to the current I_{M1} that passes through the transistor M1 during the on period of the transistor M1. The current I_{M1} contains information on the inductor current I_{L}.

The main comparator 14 compares the slope voltage V_{SLP} with the error voltage V_{CMP} to output a signal RST, which is a digital signal representing the result of the comparison. If the slope voltage V_{SLP} is higher than the error voltage V_{CMP}, the signal RST is at high level; if the slope voltage V_{SLP} is lower than the error voltage V_{CMP}, the signal RST is at low level. If the slope voltage V_{SLP} is equal to the error voltage V_{CMP}, the signal RST is at high or low level. Of different output signals RST from the main comparator 14, only a high-level signal RST functions as a reset signal and a low-level signal RST does not. In the following description, the output of a high-level signal RST from the main comparator 14 is occasionally referred to as the release or output of a reset signal. The main comparator 14 functions as a reset signal releasing circuit that releases a reset signal based on the slope voltage V_{SLP} and the error voltage V_{CMP}.

The set signal releasing circuit 15 feeds a signal SET, which is a digital signal, to the PWM circuit 16. Of different output signals SET from the set signal releasing circuit 15, only a high-level signal SET functions as a set signal and a low-level signal SET does not. In the following description, the output of a high-level signal SET from the set signal releasing circuit 15 is occasionally referred to as the release or output of a set signal. The set signal releasing circuit 15 can release the set signal periodically at a predetermined frequency f_{CLK}. Specifically, as shown in FIG. 3, the set signal releasing circuit 15 can produce up edges in the signal SET at time intervals equal to the reciprocal of the predetermined frequency f_{CLK}. The signal SET contains pulses that remain at high level only for a predetermined minute period of time, and in the signal SET those pulses occur cyclically at time intervals equal to the reciprocal of the frequency f_{CLK}.

The PWM circuit 16 is configured with a logic circuit such as a flip-flop, and generates and output a control signal CNT for specifying the on/off states of the transistors M1 and M2 based on the signal SET from the set signal releasing circuit 15 and the signal RST from the main comparator 14. Based on the control signal CNT, the gate driver 17 controls the gate signal G1 for the transistor M1 and the gate signal G2 for the transistor M2.

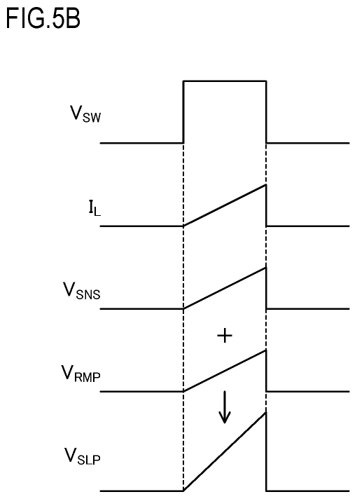

FIG. 4 shows the relationship among the signals SET, RST, CNT, G1, and G2. The signals SET, RST, CNT, G1, and G2 are each a binary signal that is at high or low level at a time. If with the signal RST at low level a high-level signal SET is fed to the PWM circuit 16 (i.e., when a set signal is released), the control signal CNT turns to high level and is then held at high level until a high-level signal RST is fed to the PWM circuit 16 (i.e., until a reset signal is released). If with the signal SET at low level a high-level signal RST is fed to the PWM circuit 16 (i.e., when a reset signal is released), the control signal CNT turns to low level and is then held at low level until a high-level signal SET is fed to the PWM circuit 16 (i.e., until a set signal is released). In a period in which the signals SET and RST are both at low level, the control signal CNT is kept at the held level. In the control block 10, it does not occur that the signals SET and RST are simultaneously at high level.

In the high-level period of the control signal CNT, the gate driver 17 keeps the gate signals G1 and G2 at high and low levels respectively so as to keep the output stage circuit 20 in the high-output state. In the low-level period of the control signal CNT, the gate driver 17 keeps the gate signals G1 and G2 at low and high levels respectively so as to keep the output stage circuit 20 in the low-output state. On detection of a reverse current or on occurrence of a fault, control proceeds differently than as described above, of which, however, no description will be given here. A reverse current denotes a current that passes from the inductor L1 via the node ND1 and the transistor M2 to the ground.

Configured as described above, the control block 10 performs switching operation based on the feedback voltage V_{FB} and the slope voltage V_{SLP} so as to turn on and off the transistors M1 and M2 alternately (i.e., switches the output stage circuit 20 between the high-output state and the low-output state); it can thereby stabilize the output voltage V_{OUT} at a predetermined target voltage V_{TG}. Note that, in switching operation, turning on and off the transistors M1 and M2 alternately does not exclude a both-off state being provided with consideration given to a dead time or the like during a transition between the low-output state and the high-output state.

Through the switching operation described above, the output stage circuit 20 switches the input voltage V_{IN}. That is, through the switching operation, a voltage with a rectangular waveform of which the level varies between substantially the level of the input voltage V_{IN} and the level of the ground appears as the switching voltage V_{SW}. This switching voltage V_{SW} is rectified and smoothed by the inductor L1 and the output capacitor C1 to produce a direct-current output voltage V_{OUT}.

In the control block 10, throughout the switching operation described above, feedback control is performed so as to reduce the differential voltage between the feedback voltage V_{FB} and the reference voltage V_{REF} (in other words, control so as to keep the differential voltage zero). Accordingly, the target voltage V_{TG} of the output voltage V_{OUT} depends on the reference voltage V_{REF}. Moreover, in the switching power supply device AP, the output voltage V_{OUT} itself is used as the feedback voltage V_{FB}, and thus the target voltage V_{TG} is equal to the reference voltage V_{REF}, with the result that feedback control is performed so as to stabilize the output voltage V_{OUT} at the reference voltage V_{REF}.

Here is a supplementary description of the slope voltage V_{SLP}. The current I_{M1} that passes through the transistor M1 in its on period is equal to the inductor current I_{L} during the on period of the transistor M1; thus the slope voltage V_{SLP} conveys information on the inductor current I_{L} during the on period of the transistor M1. That is, the slope voltage V_{SLP} contains current information on the transistor M1 or the inductor L1 during the on period of the transistor M1. The slope voltage V_{SLP} containing such current information can be generated by any known method. FIG. 5A shows an example of the configuration of the slope voltage generation circuit 13, and FIG. 5B shows the waveform of the current and voltages associated with the slope voltage V_{SLP}. The slope voltage generation circuit 13 in FIG. 5A includes an IV converter 13a, a ramp voltage generation circuit 13b, and an adder 13c. The IV converter 13a converts the current I_{M1} that passes through the transistor M1 during its on period (i.e., the inductor current I_{L} during the on period of the transistor M1) into a voltage and thereby generates a sense voltage V_{SNS} proportional to the current I_{M1}. The ramp voltage generation circuit 13b generates a ramp voltage V_{RMP} with a sawtooth waveform that, starting at 0 V, gradually increases during the on period of the transistor M1. The adder 13c yields, as the slope voltage V_{SLP}, the sum of the sense voltage V_{SNS} and the ramp voltage V_{RMP}. During any period outside the on period of the transistor M1, the slope voltage V_{SLP} is at 0 V (through it may have a predetermined bias voltage value). As is well known, adding the ramp voltage V_{RMP} helps suppress oscillation of an output feedback loop in current-mode control.

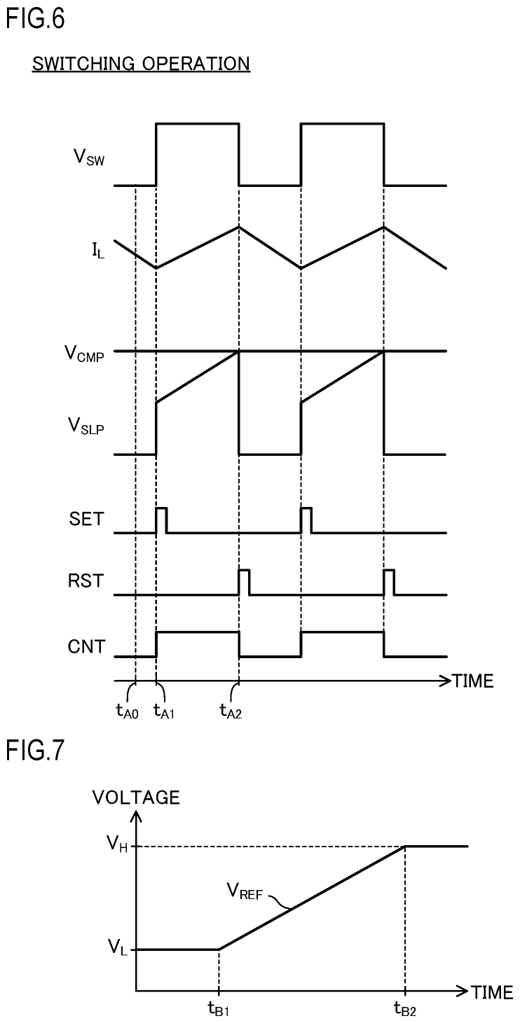

FIG. 6 is a timing chart of the switching operation performed in the feedback control. A time point, t_{A0}, at which the control signal CNT is at low level and the signal SET is at low level is taken as the starting point. At time point t_{A0}, the slope voltage V_{SLP} is at 0 V; after that, at time point t_{A1}, an up edge appears in the signal SET. That is, at time point t_{A1}, a set signal is released. In response to the release of the set signal, the control signal CNT turns from low level to high level, and thus the output stage circuit 20 turns from the low-output state to the high-output state. During the period in which the output stage circuit 20 is in the high-output state, the inductor current I_{L} increases gradually and together the slope voltage V_{SLP} increases gradually. When the slope voltage V_{SLP}, which has been lower than the error voltage V_{CMP}, reaches the error voltage V_{CMP} at time point t_{A2}, the output signal RST of the main comparator 14 turns from low level to high level. That is, a reset signal is released. In response to the release of the reset signal, the control signal CNT turns from high level to low level, and thus the output stage circuit 20 turns from the high-output state to the low-output state. With the output stage circuit 20 in the low-output state, the slope voltage V_{SLP} quickly falls to 0 V, and thus the signal RST turns back to low level. Thereafter, similar operation repeats.

The set signal is released repeatedly at intervals equal to the reciprocal of the frequency f_{CLK}, and thus the transistors M1 and M2 are PWM-controlled at the frequency f_{CLK}. That is, the switching power supply device AP performs pulse-width modulation on the input voltage V_{IN} at the frequency f_{CLK} to produce the output voltage V_{OUT}. The frequency f_{CLK} may be constant, or may be varied within a predetermined frequency range by a spread spectrum technology. Though not specifically illustrated, with reference to a given state, a decrease in the current consumption of the load LD causes a drop in the error voltage V_{CMP}, a drop in the average value of the inductor current I_{L}, and a drop in the output duty and an increase in the current consumption of the load LD causes a rise in the error voltage V_{CMP}, a rise in the average value of the inductor current I_{L}, and a rise in the output duty; thus the output voltage V_{OUT} is kept at the target voltage V_{TG}. The output duty denotes the ratio of the period in which the output stage circuit 20 is in the high-output state to the sum of the period in which the output stage circuit 20 is in the high-output state and period in which the output stage circuit 20 is in the low-output state.

FIG. 7 shows how the reference voltage V_{REF} varies. At time point t_{B1} after the start of the supply of the input voltage V_{IN} to the input terminal IN, the reference voltage V_{REF} has a predetermined lower-limit voltage V_{L}. From time point t_{B1} to time point t_{B2}, which occurs later than time point t_{B1}, the reference voltage feeding circuit 12 monotonically raises the reference voltage V_{REF} from the predetermined lower-limit voltage V_{L} to a predetermined upper-limit voltage V_{H}; after time point t_{B2}, the reference voltage feeding circuit 12 holds the reference voltage V_{REF} at the upper-limit voltage V_{H}. The lower-limit voltage V_{L} is 0 V (zero volts), and the upper-limit voltage V_{H} is equal to the target voltage V_{TG} of the output voltage V_{OUT}. This achieves, at the start-up of the semiconductor device 1 and the switching power supply device AP, soft-start operation in which the output voltage V_{OUT} is raised gradually from 0 V to the target voltage V_{TG}. The switching operation described with reference to FIG. 6 is performed in any period after time point t_{B1}. Note that the lower-limit voltage V_{L} may be a voltage other than 0 V (so long as V_{L}<V_{H}).

### Reference Example

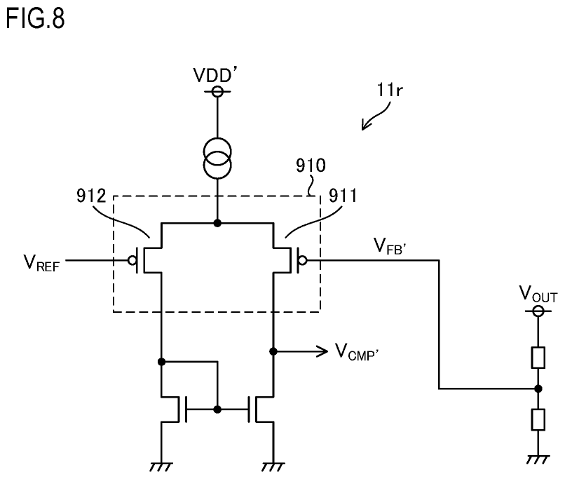

The semiconductor device 1 has a unique configuration in the error amplifier 11. Prior to a description of this unique configuration, the configuration of an error amplifier 11r according to a reference example is shown in FIG. 8. The error amplifier 11r according to the reference example includes a differential input pair 910 composed of transistors 911 and 912. The gate of the transistor 911 is fed with, as a feedback voltage V_{FB}′, a division voltage of the output voltage V_{OUT}, and the gate of the transistor 912 is fed with the reference voltage V_{REF}. The error amplifier 11r generates an error voltage V_{CMP}′ corresponding to the differential voltage between the feedback voltage V_{FB}′ and the reference voltage V_{REF}. At the start-up of the semiconductor device 1 and the switching power supply device AP, the reference voltage V_{REF} has a voltage close to 0 V; thus, if the transistors 911 and 912 are of an N-channel type, it is not possible to secure a gate-source voltage that the transistors 911 and 912 need to operate, and the differential input pair 910 does not operate properly (it cannot generate the error voltage V_{CMP}′ corresponding to the differential voltage between the feedback voltage V_{FB}′ and the reference voltage V_{REF}). For this reason, in the error amplifier 11r, the transistors 911 and 912 are formed as P-channel MOSFETs.

While the error amplifier 11r can be configured such that V_{FB}′=V_{OUT}, doing so requires that the supply voltage V_{DD}′ for the error amplifier 11r be set to be higher than the sum of the output voltage V_{OUT} and the gate threshold voltage of P-channel MOSFETs. This is disadvantageous for power saving and the like. For the error amplifier 11r to operate properly under the restriction that the supply voltage V_{DD}′ cannot be raised, the output voltage V_{OUT} needs to be resistor-divided. Accordingly, in the configuration in FIG. 8, the output voltage V_{OUT} is resistor-divided to produce a division voltage of the output voltage V_{OUT}, and this division voltage is used as the feedback voltage V_{FB}′ to the error amplifier 11r.

Inconveniently, resistor-dividing the output voltage V_{OUT} results in higher noise in the output voltage V_{OUT}. This will now be described by way of a simple numerical example. Consider a case where the target voltage V_{TG} of the output voltage V_{OUT} is 0.9 v and v_{fb}′=(⅓)vₒᵤₜ. in this case, the reference voltage v_{ref} after the completion of soft-start operation (i.e., the upper-limit voltage V_{H}) is set to 0.3 V. For the sake of discussion, suppose that, after the completion of soft-start operation, the reference voltage V_{REF} deviates from the set voltage, 0.3 V, by 0.1 V due to noise to become 0.4 V; then the feedback control in the reference example brings the output voltage V_{OUT} to 1.2 V. That is, the output voltage V_{OUT} deviates from the target voltage V_{TG} by as high as 0.3 V. On the other hand, in the numerical example under discussion, if V_{FB}′=V_{OUT}, the reference voltage V_{REF} after the completion of soft-start operation (i.e., the upper-limit voltage V_{H}) is set to 0.9 V. Then, even if the reference voltage V_{REF} deviates from the set voltage, 0.9 V, by 0.1 V to become 1.0 V, the output voltage V_{OUT} is brought to 1.0 V, and hence the output voltage V_{OUT} deviates from the target voltage V_{TG} by only 0.1 V.

As discussed above, resistor-dividing the output voltage V_{OUT} leads to increased noise in the output voltage V_{OUT}. Thus, although avoiding resistor-dividing the output voltage V_{OUT} is advantageous for noise suppression, resistor division is inevitable with the configuration in FIG. 8 due to the restriction on the supply voltage V_{DD}′ and the like.

With what has been discussed above taken into consideration, a configuration that contributes to suppressed noise in the output voltage V_{OUT} is adopted in the error amplifier 11. From here on, a plurality of practical examples will be presented by way of which some specific examples of the configuration of the switching power supply device AP (in particular, the error amplifier 11) will be described along with applied and modified technologies and other features associated with them. Unless otherwise stated or unless incompatible, any part of the description given above in connection with the embodiment (except parts directed to the reference example) is applicable to the practical examples described below. For any description of the practical examples that contradict what has described above, that description given in connection with the practical examples can prevail. Unless incompatible, any description given in connection with any of the plurality of practical examples described below is applicable to any other of the practical examples (that is, any two or more of the practical examples can be combined together).

### Practical Example 1

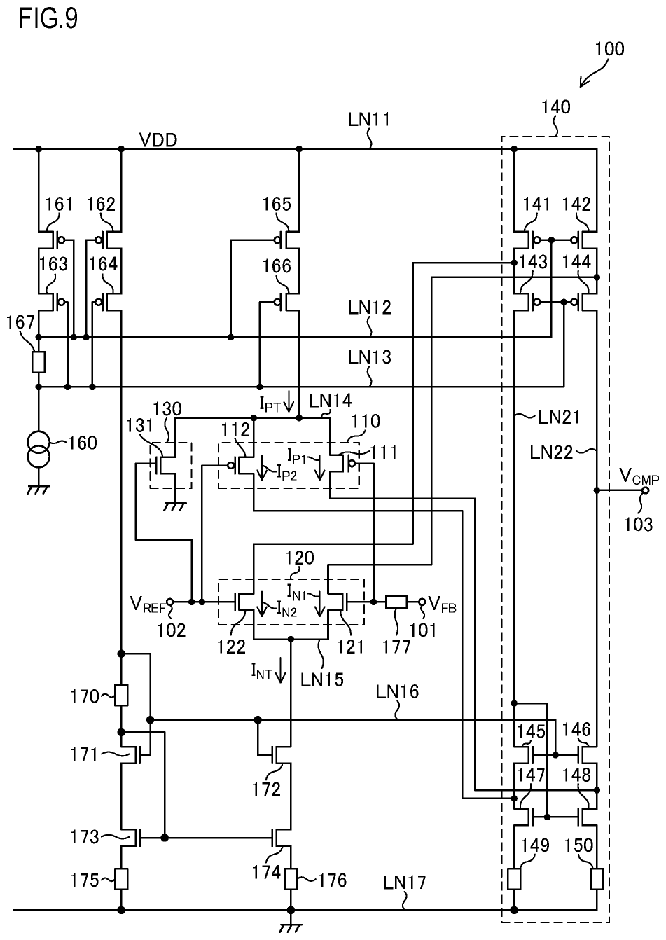

Practical Example 1 will be described. FIG. 9 is a circuit diagram of an error amplifier 100 of Practical Example 1. In Practical Example 1, the error amplifier 100 is used as the error amplifier 11 in FIG. 1. In short, in Practical Example 1 is configured as follows. The output voltage V_{OUT} is not resistor-divided and is itself used as the feedback voltage V_{FB}. At the start-up of the semiconductor device 1 and the switching power supply device AP (during the execution of soft-start operation), a differential input pair 110 composed of P-channel MOSFETs is used to generate the error voltage V_{CMP}. After the completion of the start-up of the semiconductor device 1 and the switching power supply device AP (after the completion of soft-start operation), a differential input pair 120 composed of N-channel MOSFETs is used to generate the error voltage V_{CMP}. Now, the configuration and operation of the error amplifier 100 in FIG. 9 will be described in detail.

The error amplifier 100 includes transistors 111, 112, 121, 122, 131, 141 to 148, 161-166, and 171-174. Of these transistors, the transistors 111, 112, 141 to 144 and 161 to 166 are formed as P-channel MOSFETs, and the transistors 121, 122, 131, 145 to 148, and 171 to 174 are formed as N-channel MOSFETs.

The error amplifier 100 also includes a constant current source 160 and resistors 149, 150, 167, 170, and 175 to 177. A plurality of lines shown in FIG. 9, including lines LN11 to LN17, LN21, and LN22, are also components of the error amplifier 100. The line LN11 is a power line to which a supply voltage V_{DD} is applied. The supply voltage V_{DD} has a predetermined positive direct-current voltage value (e.g., 1.5 V). The supply voltage V_{DD} can be generated by the internal power supply circuit 30 (see FIG. 1). The line L17 is a ground line at a ground potential (i.e., a potential of 0 V)

The error amplifier 100 further includes terminals 101 to 103. The terminals 101 and 102 are the inverting input terminal and the non-inverting input terminal, respectively, of the error amplifier 100. Accordingly, the terminals 101 and 102 function as the inverting input terminal and the non-inverting input terminal, respectively, of the error amplifier 11 in FIG. 1, the terminal 101 being fed with the feedback voltage V_{FB} and the terminal 102 being fed with the reference voltage V_{REF}. The terminal 103 is the output terminal of the error amplifier 100. Accordingly, the terminal 103 functions as the output terminal of the error amplifier 11 in FIG. 1, the terminal 103 being connected, outside the error amplifier 100, to the line LN1 in FIG. 1 (how it is connected to the line LN1 is not illustrated in FIG. 9).

The transistors 111 and 112 constitute a differential input pair 110 (first differential input pair). The transistors 111 and 112 are two P-channel MOSFETs with identical structures. Moreover, so that transistors 111 and 112 may have equal temperatures, they are arranged close to each other. The transistors 121 and 122 constitute a differential input pair 120 (second differential input pair). The transistors 121 and 122 are two N-channel MOSFETs with identical structures. Moreover, so that transistors 121 and 122 may have equal temperatures, they are arranged close to each other. Preferably, N-channel MOSFETs with high noise immunity (in other words, low-noise N-channel MOSFETs) can be used as the transistors 111 and 112.

The transistor 131 constitutes a path switching circuit 130. The function of the path switching circuit 130 will be described later. The transistors 141 to 148 and the resistors 149 and 150 constitute an error voltage generation circuit 140.

The circuit elements of the error amplifier 100 are interconnected as follows. The sources of the transistors 161, 162, 165, 141, and 142 are connected to the power line LN11. Between the source of each of the transistors 161, 162, 165, 141, and 142 and the line LN1, a resistor may be inserted, one at a place. The gates of the transistors 161, 162, 165, 141, and 142 and the drain of the transistor 163 are all connected to the line LN12. The drains of the transistors 161, 162, 165, 141, and 142 are connected to the sources of the transistors 163, 164, 166, 143, and 144 respectively. The gates of the transistors 163, 164, 166, 143, and 144 are all connected to the line LN13. The drain of the transistor 163 is connected via the resistor 167 to the line LN13. The constant current source 160 is provided between the line LN13 and the ground.

The drain of the transistor 166 is connected to the line LN14. To the line LN14 are also connected the sources of the transistors 111 and 112 and the drain of the transistor 131. The gates of the transistors 111 and 121 are connected together. The gates of the transistors 111 and 121 are connected via the resistor 177 to the terminal 101. The resistor 177 may be omitted, in which case the gates of the transistors 111 and 121 are connected directly to the terminal 101. In either case, the gates of the transistors 111 and 121 are fed with the feedback voltage V_{FB}. The gates of the transistors 112, 122, and 131 are connected together, and the gates of the transistors 112, 122, and 131 are connected to the terminal 102. Thus, the gates of the transistors 112 and 122 are fed with the reference voltage V_{REF}, and also the gate of the transistor 131 is fed with the reference voltage V_{REF}. The source of the transistor 131 is connected to the ground.

The drain of the transistor 143, the drain of the transistor 145, and the gates of the transistors 147 and 148 are all connected to the line LN21. The drain of the transistor 144 and the drain of the transistor 146 are both connected to the line LN22. The line LN22 is connected to the terminal 103. The source of the transistor 145, the drain of the transistor 147, and the drain of the transistor 112 are connected together. The source of the transistor 146, the drain of the transistor 148, and the drain of the transistor 111 are connected together. The source of the transistor 147 is connected via the resistor 149 to the ground line LN17, and the source of the transistor 148 is connected via the resistor 150 to the ground line LN17.

The drain of the transistor 121 is connected to the drain of the transistor 142 and to the source of the transistor 144. The drain of the transistor 122 is connected to the drain of the transistor 141 and to the source of the transistor 143. The sources of the transistors 121 and 122 and the drain of the transistor 172 are all connected to the line LN15. The source of the transistor 172 is connected to the drain of the transistor 174. The source of the transistor 174 is connected via the resistor 176 to the ground line LN17.

The drain of the transistor 164 and the gates of the transistors 171, 172, 145, and 146 are all connected to the line LN16. The drain of the transistor 164 is connected via the resistor 170 to the drain of the transistor 171. The drain of the transistor 171 is connected to the gates of the transistors 173 and 174. The source of the transistor 171 is connected to the drain of the transistor 173. The source of the transistor 173 is connected via the resistor 175 to the ground line LN17.

The operation of the error amplifier 100 will now be described. The constant current source 160 performs constant current operation to pass a predetermined constant current from the line LN13 to the ground. As the constant current source 160 performs constant current operation, drain currents pass through the transistors 161 to 164 and a positive voltage is applied to the line LN16, turning on the transistors 171, 172, 145, and 146, which function as switches. This brings a state where drain currents pass through the transistors 171 to 174 and drain currents pass also through the transistors 141 to 148. With no constant current operation, no drain currents pass through the transistors in the error amplifier 100, which thus ceases to operate. The control block 10 (see FIG. 1) can enable or disable the constant current operation by the constant current source 160. At least after time point t_{B1} in FIG. 7, the constant current source 160 performs constant current operation all the time. The following description assumes that the constant current source 160 is continuously performing constant current operation.

The transistors 165 and 166 operate together with the transistors 161 and 163, the resistor 167, and the constant current source 160 to generate a constant current I_{PT} with a first predetermined current value. Thus, the error amplifier 100 includes a first constant current generation circuit that generates the constant current I_{PT}. While the main components of the first constant current generation circuit are the transistors 165 and 166, also the transistors 161 and 163, the resistor 167, and the constant current source 160 can be understood to be included among the components of the first constant current generation circuit. The constant current I_{PT} passes from the power line LN11 via the transistors 165 and 166 to the line LN14.

The transistor 174 and the resistor 176 operate together with the transistor 173 and the resistor 175, the transistors 162 and 164, and the constant current source 160 to generate a constant current I_{NT} with a second predetermined current value. Thus, the error amplifier 100 includes a second constant current generation circuit that generates the constant current I_{NT}. While the main components of the second constant current generation circuit are the transistor 174 and the resistor 176, also the transistor 173 and the resistor 175, the transistors 162 and 164, and the constant current source 160 may be understood to be included among the components of the second constant current generation circuit. The constant current I_{NT} passes from the line LN15 via the transistors 172 and 174 and the resistor 176 to the ground line LN17.

Note that it is only after the voltages V_{FB} and V_{REF} fed to the terminals 101 and 102 have risen sufficiently that the second constant current generation circuit functions such that the constant current I_{NT} has the second predetermined current value. Specifically, for example, when the voltages V_{FB} and V_{REF} are 0 V or close to 0 V, substantially no currents pass through the transistors 121 and 122, and thus the constant current I_{NT}, which should correspond to the sum of the drain currents through the transistors 121 and 122, substantially has a value of zero. At least when the voltages V_{FB} and V_{REF} are equal to the upper-limit voltage V_{H} or when they are lower than the upper-limit voltage V_{H} but have a voltage value close to the upper-limit voltage V_{H}, the constant current I_{NT} has the second predetermined current value.

In the following description, the drain current through the transistor 111 is occasionally identified by the symbol “I_{P1}” and the drain current through the transistor 112 is occasionally identified by the symbol “I_{P2}”. Likewise, the drain current through the transistor 121 is occasionally identified by the symbol “I_{N1}” and the drain current through the transistor 122 is occasionally identified by the symbol “I_{N2}”.

The path switching circuit 130 switches the path of the constant current I_{PT} between a first path and a second path based on the reference voltage V_{REF}. The first path is a path that passes across the differential input pair 110. More specifically, the first path is a path that passes across the differential input pair 110 but that does not pass across the transistor 131. The second path is a path that does not pass across the differential input pair 110. More specifically, the second path is a path that does not passes across the differential input pair 110 and that passes across the transistor 131.

In a state where the reference voltage V_{REF} is relatively low (hereinafter state ST1), the path switching circuit 130 sets the path of the constant current I_{PT} to the first path; in a state where the reference voltage V_{REF} is relatively high (hereinafter state ST2), the path switching circuit 130 sets the path of the constant current I_{PT} to the second path. The reference voltage V_{REF} in state ST2 is higher than the reference voltage V_{REF} in state ST1. Up to a point halfway in the process of the reference voltage V_{REF} rising from the lower-limit voltage V_{L} to the upper-limit voltage V_{H} (see FIG. 7), the reference voltage V_{REF} is in state ST1; when the reference voltage V_{REF} rises further from that halfway point, the reference voltage V_{REF} goes into state ST2. At least when the reference voltage V_{REF} is equal to the upper-limit voltage V_{H}, the reference voltage V_{REF} is in state ST2.

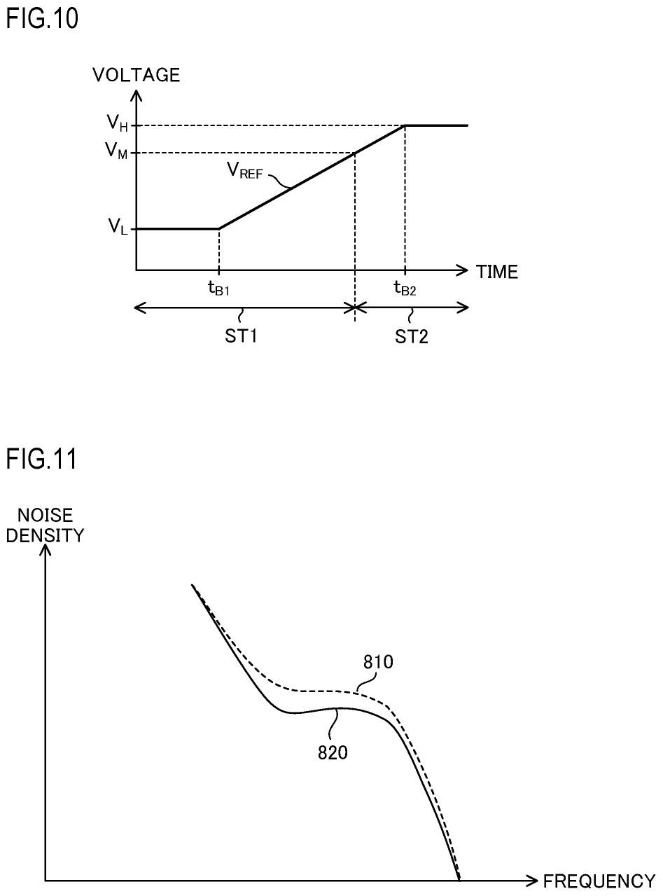

This can be put also as follows. Referring to FIG. 10, a predetermined voltage higher than the lower-limit voltage V_{L} but lower than the upper-limit voltage V_{H} will be referred to as the middle voltage V_{M}. In this case, a state where the reference voltage V_{REF} is lower than the middle voltage V_{M} corresponds to state ST1, and a state where the reference voltage V_{REF} is higher than the middle voltage V_{M} corresponds to state ST2. A state where the reference voltage V_{REF} is just equal to the middle voltage V_{M} can be classified into either state ST1 or state ST2.

In the configuration example in FIG. 9, the transistor 131 that functions as a path switching transistor (path switcher) is used to switch the path of the constant current I_{PT}. While in state ST1 the transistor 131 is off, in state ST2 the transistor 131 is on. In the configuration example in FIG. 9, the source of the transistor 131 is connected to the ground, and thus the middle voltage V_{M} corresponds to the gate threshold voltage of the transistor 131. When the gate-source voltage (the gate potential relative to the source potential) of the transistor 131 is equal to or higher than the gate threshold voltage of the transistor 131, the transistor 131 is on, and otherwise the transistor 131 is off. Note however that the source of the transistor 131 may be connected to a terminal (unillustrated) to which a fixed potential other than 0 V is applied. In any case, in a state where the reference voltage V_{REF} is lower than the middle voltage V_{M} (i.e., in state ST1), the transistor 131 is off and, in a state where the reference voltage V_{REF} is higher than the middle voltage V_{M} (i.e., in state ST2), the transistor 131 is on.

In state ST1, since the transistor 131 is off, the constant current I_{PT} is distributed between the drain current I_{P1} through the transistor 111 and the drain current I_{P2} through the transistor 112. Accordingly, in state ST1, the magnitude of the sum of the drain currents I_{P1} and I_{P2} is equal to the magnitude of the constant current I_{PT}. In state ST2, since the transistor 131 is on, the constant current I_{PT} all path through the transistor 131, with the drain currents I_{P1} and I_{P2} both zero.

Put more precisely, in the process of the reference voltage V_{REF} rising from the lower-limit voltage V_{L} to the upper-limit voltage V_{H}, a transition from state ST1 to state ST2 goes through an intermediate state, with a short duration, where drain currents pass through all the transistors 111, 112, and 131. The intermediate state corresponds to a state where, while the gate of the transistor 131 is fed with a reference voltage V_{REF} so high that a significant drain current passes through the transistor 131, the reference voltage V_{REF} is not yet high enough to allow all the constant current I_{PT} to pass between the drain and the source of the transistor 131. It should however be noted that the intermediate state, lasting for a very short time, does not have a significant effect on the operation of the error amplifier 100. Accordingly, the intermediate state will be ignored in the following description of the operation of the error amplifier 100 in the states ST1 and ST2.

First, the operation in state ST1 will be described. In state ST1, the reference voltage V_{REF} is relatively low and also the feedback voltage V_{FB}, which should be qual to the reference voltage V_{REF}, is relatively low to such a degree that no drain currents pass through either of the transistors 121 and 122. Accordingly, in state ST1, I_{N1}=I_{N2}=0, and thus the constant current I_{NT} does not pass (i.e., I_{NT}=0). Instead, in state ST1, as mentioned above, as a result of the constant current I_{PT} being distributed between the transistors 111 and 112, currents I_{P1} and I_{P2} are produced in the differential input pair 110. In state ST1, the produced currents I_{P1} and I_{P2} in the differential input pair 110 act on the error voltage generation circuit 140 such that an error voltage V_{CMP} corresponding to the produced currents I_{P1} and I_{P2} appears at the terminal 103.

In state ST1, the magnitude of the current that is supplied from the power line LN11 to the line LN21 via the transistors 141 and 143 (i.e., the magnitude of the drain currents through the transistors 141 and 143) is equal to the magnitude of the current that is supplied from the power line LN11 to the line LN22 via the transistors 142 and 144 (i.e., the magnitude of the drain currents through the transistors 142 and 144). Moreover, irrespective of in state ST1 or in state ST2, drain currents of equal magnitudes pass through the transistors 147 and 148.

In state ST1, for example, when V_{FB}=V_{REF}, then I_{P1}=I_{P2}=I_{PT}/2. Here, the magnitude of the sum current of the drain current I_{P1} through the transistor 111 and the drain current through the transistor 144 is equal to the magnitude of the sum current of the drain current I_{P2} through the transistor 112 and the drain current through the transistor 143. Thus, no current passes across the terminal 103, and the error voltage V_{CMP} does not vary.

By contrast, in state ST1, for example, when V_{FB}>V_{REF}, then I_{P1}<I_{P2}. Here, the magnitude of the sum current of the drain current I_{P1} through the transistor 111 and the drain current through the transistor 144 is lower than the magnitude of the sum current of the drain current I_{P2} through the transistor 112 and the drain current through the transistor 143. Thus, a current (positive electric charge) with a magnitude equal to the difference between those two sum currents is drawn from the terminal 103 via the transistors 146 and 148 to the ground line LN17. As a result, the error voltage V_{CMP} drops. A drop in the error voltage V_{CMP} leads to a drop in the output duty, and thus the difference between voltages V_{FB} and V_{REF} reduces. In state ST1, when V_{FB}<V_{REF}, operation proceeds in the opposite way compared with when V_{FB}>V_{REF}.

As described above, in state ST1, based on the constant current I_{PT} the differential input pair 110 produces currents (I_{P1} and I_{P2}) corresponding to the differential voltage between the feedback voltage V_{FB} and the reference voltage V_{REF}, and based on the produced currents (I_{P1} and I_{P2}) in the differential input pair 110 the error voltage generation circuit 140 generates an error voltage V_{CMP} corresponding to those produced currents (I_{P1} and I_{P2}).

Next, the operation in state ST2 will be described. Irrespective of in state ST1 or in state ST2, the drain current through the transistor 141 and the drain current through the transistor 142 have equal magnitudes. Moreover, irrespective of in state ST1 or in state ST2, drain currents of equal magnitudes pass through the transistors 147 and 148.

In state ST2, the reference voltage V_{REF} is relatively high and also the feedback voltage V_{FB}, which should be qual to the reference voltage V_{REF}, is relatively high; thus the second constant current generation circuit configured to include the transistor 174 so functions that drain currents I_{N1} and I_{N2} pass through the transistors 121 and 122. That is, based on the constant current I_{NT}, the drain currents I_{N1} and I_{N2} are produced in the differential input pair 120, and the sum of the drain currents I_{N1} and I_{N2} here corresponds to the constant current I_{NT}. On the other hand, in state ST2, as mentioned above, no drain currents pass through the transistors 111 and 112 (i.e., I_{P1}=I_{P2}=0). In state ST2, the produced currents I_{N1} and I_{N2} in the differential input pair 120 act on the error voltage generation circuit 140 such that an error voltage V_{CMP} corresponding to the produced currents I_{N1} and I_{N2} appears at the terminal 103.

In state ST2, when, for example, V_{FB}=V_{REF}, then I_{N1}=I_{N2}=I_{NT}/2. Here, a current that is left after subtracting the drain current I_{N2} through the transistor 122 from the drain current through the transistor 141 passes through the transistor 143, and a current that is left after subtracting the drain current I_{N1} through the transistor 121 from the drain current through the transistor 142 passes through the transistor 144. Thus, when I_{N1}=I_{N2}=I_{NT}/2, the drain current through the transistor 143 and the drain current through the transistor 144 have equal magnitudes. Then, the drain current through the transistor 143 and the drain current through the transistor 144 with equal magnitudes pass as the drain current through the transistor 147 and the drain current through the transistor 148 respectively; thus no current passes across the terminal 103, and the error voltage V_{CMP} does not vary.

By contrast, in state ST2, when, for example, V_{FB}>V_{REF}, then I_{N1}>I_{N2}. Here, a current that is left after subtracting the drain current I_{N2} through the transistor 122 from the drain current through the transistor 141 passes through the transistor 143, and a current that is left after subtracting the drain current I_{N1} through the transistor 121 from the drain current through the transistor 142 passes through the transistor 144. Thus, when I_{N1}>I_{N2}, the drain current through the transistor 144 is lower than the drain current through the transistor 143. Thus, a current (positive electric charge) with a magnitude equal to the difference between the drain current through the transistor 144 and the drain current through the transistor 143 is drawn from the output terminal 103 via the transistors 146 and 148 to the ground line LN17. As a result, the error voltage V_{CMP} drops. A drop in the error voltage V_{CMP} leads to a drop in the output duty, and thus the difference between the voltages V_{FB} and V_{REF} reduces. In state ST2, when V_{FB}<V_{REF}, operation proceeds in the opposite way compared with when V_{FB}>V_{REF}.

As described above, in state ST2, based on the constant current I_{NT} the differential input pair 120 produces currents (I_{N1} and I_{N2}) corresponding to the differential voltage between the feedback voltage V_{FB} and the reference voltage V_{REF}, and based on the produced currents (I_{N1} and I_{N2}) in the differential input pair 120 the error voltage generation circuit 140 generates an error voltage V_{CMP} corresponding to those produced currents (I_{N1} and I_{N2}).

FIG. 11 shows the results of simulations performed for comparison between the reference example and Practical Example 1. In FIG. 11, a broken-line curve 810 represents the frequency dependence of the noise density of the output voltage V_{OUT} as observed when the error amplifier 11r of the reference example (FIG. 8) is used as the error amplifier 11 in FIG. 1. A solid-line curve 820 represents the frequency dependence of the noise density of the output voltage V_{OUT} as observed when the error amplifier 100 of Practical Example 1 (FIG. 9) is used as the error amplifier 11 in FIG. 1. Except for differences in the configuration of the error amplifier 11, the simulations that yielded the curves 810 and 820 were performed under the same conditions. In the reference example, a division voltage obtained by resistor-dividing the output voltage V_{OUT} by a factor of ⅓ was used as the feedback voltage V_{FB}′ (see FIG. 8). The results reveal that, compared with the reference example, the configuration of Practical Example 1 exhibits enhanced characteristics in terms of noise.

The noise density here denotes noise density as observed after the reference voltage V_{REF} has reached the upper-limit voltage V_{H}. The noise in the output voltage V_{OUT} that has to be reduced in the switching power supply device AP is the noise observed with the output voltage V_{OUT} stabilized at the target voltage V_{TG}; the magnitude of the noise during the execution of soft starting does not matter.

As described above, in the switching power supply device AP, in state ST1 at start-up, the differential input pair 110 composed of P-channel MOSFETs is used to generate the error voltage V_{CMP} and thereafter, in state ST2, the differential input pair 120 composed of N-channel MOSFETs is used to generate the error voltage V_{CMP}. In this way it is possible to use the output voltage V_{OUT} itself as the feedback voltage V_{FB} with no restrictions such as the need for a high supply voltage V_{DD}, and thus to reduce noise in the output voltage V_{OUT}.

Moreover, owing to the provision of the path switching circuit 130, once the reference voltage V_{REF} becomes sufficiently high, no currents pass through the transistors 111 and 112; thus no malfunctioning ascribable to currents through transistors 111 and 112 occurs. That is, once the reference voltage V_{REF} becomes sufficiently high, of the transistors 111, 112, 121, and 122, only the transistors 121 and 122, which are N-channel MOSFETs, operate to generate the error voltage V_{CMP} properly.

### Practical Example 2

Practical Example 2 will now be described. Vehicles such as automobiles are often equipped with a radar device. A radar device mounted on a vehicle (hereinafter referred to as a vehicle-mounted radar device) can sense the distance from the vehicle to an object present outside the vehicle, the speed of the object (the relative speed between the vehicle and the object), and the like. A supply voltage for a vehicle-mounted radar device is required to be a low-noise direct-current voltage. This is because noise in the supply voltage for a vehicle-mounted radar device adversely affects its sensing accuracy; hence expectations are high today for noise suppression.

In general, compared with DC/DC converters, LDO (low-dropout) regulators classified as linear regulators suffer less noise. For this reason, according to a commonly adopted scheme, an LDO regulator is driven with the output voltage of a DC/DC converter and a vehicle-mounted radar device is driven with the output voltage of the LDO regulator. Inconveniently, this scheme invites an increased heat loss and an increased number of components. Thus, aiming at high efficiency and compactness, many studies have been made on a scheme of driving a vehicle-mounted radar device with a DC/DC converter alone. This requires a DC/DC converter that is low-noise on its own.

This requirement is met with the switching power supply device AP that includes the error amplifier 100 of Practical Example 1. Accordingly, the output voltage V_{OUT} of the switching power supply device AP that employs the error amplifier 100 as the error amplifier 11 in FIG. 1 can be usefully used as a supply voltage for a vehicle-mounted radar device. That is, a vehicle-mounted radar device is a suitable example of the load LD in FIG. 1.

It should however be noted that, in the present disclosure, the load LD is not limited to a vehicle-mounted radar device. The load LD may be any type of sensor device that is not classified as a radar device, or may be any electronic device.

### Practical Example 3

Practical Example 3 will now be described. Practical Example 3 deals with modified and applied technologies associated with the configurations described above.

So long as the path of the constant current I_{PT} can be switched between the first and second paths based on the reference voltage V_{REF} as described above, the configuration of the path switching circuit 130 can be modified in any way. For example, the path switching circuit 130 may include a comparator that compares the reference voltage V_{REF} with the middle voltage V_{M} and a switching transistor that is inserted between the line LN14 and the ground. In that case, when V_{REF}<V_{M}, the switching transistor can be kept off so that the path of the constant current I_{PT} is set to the first path and, when V_{REF}>V_{M}, the switching transistor can be kept off so that the path of the constant current I_{PT} is set to the second path. Likewise, the first constant current generation circuit can have any configuration so long as it can generate the constant current I_{PT} and the second constant current generation circuit can have any configuration so long as it can generate the constant current I_{NT}. Likewise, the configuration of the error voltage generation circuit 140 can be modified in any way.

The control block 10 includes an output stage control circuit that controls the output stage circuit 20 based on the error voltage V_{CMP} so as to reduce the difference between the feedback voltage V_{FB} and the reference voltage V_{REF} (in other words, such that the feedback voltage V_{FB} remains equal to, or follows, the reference voltage V_{REF}). In the configuration in FIG. 1, the output stage control circuit is constituted by the slope voltage generation circuit 13, the main comparator 14, the set signal releasing circuit 15, the PWM circuit 16, and the gate driver 17.

The above description deals with an example where the state of the output stage circuit 20 is controlled by current-mode control based on information on the output voltage V_{OUT} (i.e., the feedback voltage V_{FB}) and information on the inductor current I_{L}. Instead, the control block 10 may adopt a scheme of controlling the state of the output stage circuit 20 based on information on the output voltage V_{OUT} (i.e., the feedback voltage V_{FB}) without referring to information on the inductor current I_{L}.

While the above description deals with, as an example, a switching power supply device AP configured as a buck (step-down) DC/DC converter, it is also possible to configure an switching power supply device AP as a boost (step-up) DC/DC converter or a buck-boost (step-down/up) DC/DC converter.

For any signal or voltage, the relationship of its high and low levels may be reversed unless inconsistent with what is disclosed herein.

Unless incompatible, any transistor mentioned above can be a transistor of any type. For example, unless incompatible, any transistor mentioned above as a MOSFET can be replaced with a junction FET, IGBT (insulated-gate bipolar transistor), or bipolar transistor. Any transistor has a first electrode, a second electrode, and a control electrode. In an FET, of the first and second electrodes one is the drain and the other is the source, and the control electrode is the gate. In an IGBT, of the first and second electrodes one is the collector and the other is the emitter, and the control electrode is the gate. In a bipolar transistor that is not classified as an IGBT, of the first and second electrodes one is the collector and the other is the emitter, and the control electrode is the base.

In the present disclosure, whenever a first physical quantity and a second physical quantity are mentioned to be equal, that allows for an error. That is, whenever a first physical quantity and a second physical quantity are mentioned to be equal, it means that designing or manufacturing is done with an aim of making the first and second physical quantities equal; thus even if in reality there is an error between the first and second physical quantities, these are to be understood to be equal. This applies likewise to anything other than physical quantities.

Embodiments of the present disclosure can be modified in many ways as necessary without departure from the scope of the technical concepts defined in the appended claims. The embodiments described herein are merely examples of how the present disclosure can be implemented, and what is meant by any of the terms used to describe the subject matter of the present disclosure and its constituent elements is not limited to that mentioned in connection with the embodiments. The specific values mentioned in the above description are merely illustrative and needless to say can be modified to different values.

### NOTES

To follow are supplementary notes on the present disclosure.

According to one aspect of the present disclosure, an amplifier circuit (11, 100; see FIGS. 1 and 9) configured to generate an error voltage (V_{CMP}) corresponding the difference between a target voltage (V_{FB}) and a reference voltage (V_{REF}) includes: a first differential input pair (110) having a first transistor (111) configured to receive the target voltage at its gate and a second transistor (112) configured to receive the reference voltage at its gate; and a second differential input pair (120) having a third transistor (121) configured to receive the target voltage at its gate; and a fourth transistor (122) configured to receive the reference voltage at its gate. The amplifier circuit generates the error voltage based on the reference voltage by using the first or second differential input pair. The first and second transistors are formed as P-channel MOSFETs and the third and fourth transistors are formed as N-channel MOSFETs. (A first configuration.)

The target voltage for the amplifier circuit of the first configuration corresponds to the feedback voltage V_{FB} in the switching power supply device AP in FIG. 1. However, the target voltage for the amplifier circuit of the first configuration may be any voltage. It is however preferable that, in the device that incorporates the amplifier circuit, feedback control be performed so as to reduce the difference between the target voltage and the feedback voltage.

In the amplifier circuit of the first configuration (see FIGS. 7 and 10), the reference voltage may increase gradually from a predetermined first voltage (V_{L}) to a predetermined second voltage (V_{H}) and be then held at the second voltage. The amplifier circuit may generate the error voltage by using the first differential input pair in a first state (ST1) where the reference voltage is low relative to a predetermined middle voltage (V_{M}) higher than the first voltage but lower than the second voltage. The amplifier circuit may generate the error voltage by using the second differential input pair in a second state (ST2) where the reference voltage is high relative to the middle voltage. (A second configuration.)

In the amplifier circuit of the second configuration, the amplifier circuit may be provided in a switching power supply device (AP) configured to generate an output voltage (V_{OUT}) from an input voltage (VI). The target voltage may be a feedback voltage (V_{FB}) based on the output voltage. In the switching power supply device, feedback control may be performed so as to reduce the difference between the feedback voltage as the target voltage and the reference voltage. (A third configuration.)

In the amplifier circuit of the third configuration described above, the output voltage itself may be fed as the feedback voltage to the amplifier circuit. (A fourth configuration.)

The amplifier circuit of any of the second to fourth configurations described above may further include: a first constant current generation circuit configured to generate a first constant current; a second constant current generation circuit configured to generate a second constant current; and an error voltage generation circuit configured to generate the error voltage based on a current produced in the first differential input pair based on the first constant current or a current produced in the second differential input pair based on the second constant current. In the first state, the first differential input pair may produce a current corresponding to the difference between the target voltage and the reference voltage based on the first constant current so that the error voltage is generated based on the current so produced in the first differential input pair. In the second state, the second differential input pair may produce a current corresponding to the difference between the target voltage and the reference voltage based on the second constant current so that the error voltage is generated based on the current so produced in the second differential input pair. (A fifth configuration.)

The amplifier circuit of the fifth configuration described above may further include a path switching circuit configured to switch the path of the first constant current based on the reference voltage. In the first state, the path switching circuit may set the path of the first constant current to a path that passes across the first differential input pair, and in the second state, the path switching circuit may set the path of the first constant current to a path that does not pass across the first differential input pair. (A sixth configuration.)

In the amplifier circuit of the sixth configuration described above, the path switching circuit may include a path switching transistor formed as an N-channel MOSFET. The first constant current generation circuit may be provided between a supply voltage line to which a predetermined supply voltage is applied and a line to which the sources of the first and second transistors in the first differential input pair and the drain of the path switching transistor are all connected. The path switching transistor may have a gate fed with the reference voltage. In the first state, the path switching transistor may be off and, in the second state, the path switching transistor may be on. In the first state, the path switching circuit may set the path of the first constant current to a path that passes across the first differential input pair and that does not pass across the path switching transistor. In the second state, the path switching circuit may set the path of the first constant current to a path that does not pass across the first differential input pair and that passes across the path switching transistor. (A seventh configuration.)

According to another aspect of the present disclosure, a switching power supply circuit for generating an output voltage from an input voltage includes: an output stage circuit configured to perform the switching of the input voltage; a feedback voltage input terminal configured to be fed with a feedback voltage corresponding to the output voltage; the amplifier circuit of any of the first to seventh configurations described above configured to receive the feedback voltage as the target voltage; a reference voltage feeding circuit configured to feed the reference voltage to the amplifier circuit; and an output stage control circuit configured to control the output stage circuit based on the error voltage so as to reduce the difference between the feedback voltage as the target voltage and the reference voltage. (An eighth configuration.)

According to yet another aspect of the present disclosure, a switching power supply device includes: the switching power supply circuit of the eighth configuration described above; and a rectifying-smoothing circuit configured to generate the output voltage by rectifying and smoothing a voltage generated by the switching by the output stage circuit. (A ninth configuration.)

1. An amplifier circuit configured to generate an error voltage corresponding a difference between a target voltage and a reference voltage, comprising:
a first differential input pair having:
a first transistor configured to receive the target voltage at a gate thereof; and
a second transistor configured to receive the reference voltage at a gate thereof; and
a second differential input pair having:
a third transistor configured to receive the target voltage at a gate thereof; and
a fourth transistor configured to receive the reference voltage at a gate thereof.
wherein
the amplifier circuit generates the error voltage based on the reference voltage by using the first or second differential input pair, and
the first and second transistors are formed as P-channel MOSFETs and the third and fourth transistors are formed as N-channel MOSFETs.

2. The amplifier circuit according to claim 1, wherein
the reference voltage increases gradually from a predetermined first voltage to a predetermined second voltage and is then held at the second voltage,
the amplifier circuit generates the error voltage by using the first differential input pair in a first state where the reference voltage is low relative to a predetermined middle voltage higher than the first voltage but lower than the second voltage, and
the amplifier circuit generates the error voltage by using the second differential input pair in a second state where the reference voltage is high relative to the middle voltage.

3. The amplifier circuit according to claim 2, wherein
the amplifier circuit is provided in a switching power supply device configured to generate an output voltage from an input voltage,
the target voltage is a feedback voltage based on the output voltage, and
in the switching power supply device, feedback control is performed so as to reduce a difference between the feedback voltage as the target voltage and the reference voltage.

4. The amplifier circuit according to claim 3, wherein
the output voltage itself is fed as the feedback voltage to the amplifier circuit.

5. The amplifier circuit according to claim 2, further comprising:
a first constant current generation circuit configured to generate a first constant current;
a second constant current generation circuit configured to generate a second constant current; and
an error voltage generation circuit configured to generate the error voltage based on a current produced in the first differential input pair based on the first constant current or a current produced in the second differential input pair based on the second constant current,
wherein
in the first state, the first differential input pair produces a current corresponding to the difference between the target voltage and the reference voltage based on the first constant current so that the error voltage is generated based on the current so produced in the first differential input pair, and
in the second state, the second differential input pair produces a current corresponding to the difference between the target voltage and the reference voltage based on the second constant current so that the error voltage is generated based on the current so produced in the second differential input pair.

6. The amplifier circuit according to claim 5, further comprising a path switching circuit configured to switch a path of the first constant current based on the reference voltage,
wherein
in the first state, the path switching circuit sets the path of the first constant current to a path that passes across the first differential input pair, and
in the second state, the path switching circuit sets the path of the first constant current to a path that does not pass across the first differential input pair.

7. The amplifier circuit according to claim 6, wherein
the path switching circuit includes a path switching transistor formed as an N-channel MOSFET,
the first constant current generation circuit is provided between
a supply voltage line to which a predetermined supply voltage is applied and
a line to which sources of the first and second transistors in the first differential input pair and a drain of the path switching transistor are all connected,
the path switching transistor has a gate fed with the reference voltage,
in the first state, the path switching transistor is off and, in the second state, the path switching transistor is on,
in the first state, the path switching circuit sets the path of the first constant current to a path that passes across the first differential input pair and that does not pass across the path switching transistor, and
in the second state, the path switching circuit sets the path of the first constant current to a path that does not pass across the first differential input pair and that passes across the path switching transistor.

8. A switching power supply circuit for generating an output voltage from an input voltage, comprising:
an output stage circuit configured to perform switching of the input voltage;
a feedback voltage input terminal configured to be fed with a feedback voltage corresponding to the output voltage;
the amplifier circuit according to claim 1 configured to receive the feedback voltage as the target voltage;
a reference voltage feeding circuit configured to feed the reference voltage to the amplifier circuit; and
an output stage control circuit configured to control the output stage circuit based on the error voltage so as to reduce a difference between the feedback voltage as the target voltage and the reference voltage.

9. A switching power supply device, comprising:
the switching power supply circuit according to claim 8; and
a rectifying-smoothing circuit configured to generate the output voltage by rectifying and smoothing a voltage generated by the switching by the output stage circuit.
